(19) United States
(12) Patent Application Publication
(10) Pub. No.: US 2023/0006130 A1
(43) Pub. Date: Jan. 5, 2023

(54) APPARATUS FOR GENERATING, ERASING, AND MOVING SKYRMION

(71) Applicant: KOREA RESEARCH INSTITUTE OF STANDARDS AND SCIENCE, Daejeon (KR)

(72) Inventors: Seung Mo Yang, Daejeon (KR); Chan Yong Hwang, Seoul (KR); Kyoung Woong Moon, Daejeon (KR)

(21) Appl. No.: 17/583,478

(22) Filed: Jan. 25, 2022

(30) Foreign Application Priority Data
Jul. 5, 2021 (KR) 10-2021-0087900

(51) Int. Cl. H01L 43/02; H01L 27/22; H01L 43/10

(52) U.S. Cl. CPC H01L 43/02; H01L 27/222; H01L 43/10; G11C 11/1675

(57) ABSTRACT

The present disclosure relates to an apparatus for generating, erasing, and moving a skyrmion in a magnetic thin film. The apparatus for generating, erasing, and moving the skyrmion may include: a first electrode to which a first voltage for generating and erasing the skyrmion is applied; a second electrode to which a second voltage for moving the generated skyrmion is applied; a free layer having one end connected to a ground and the other end connected to the second electrode; a pinned layer which is connected to the first electrode; and a barrier layer which is provided between the free layer and the pinned layer and includes a conducting path connecting the free layer and the pinned layer.

### CROSS REFERENCE TO RELATED APPLICATIONS

This application claims the benefit under 35 USC § 119(a) of Korean Patent Application No. 10-2021-0087900 filed on Jul. 5, 2021 in the Korean Intellectual Property Office, the entire disclosure of which is incorporated herein by reference for all purposes.

### BACKGROUND

A traditional micro electronic device performs an electric charge transfer operation based on electrons, whereas a spin electronic device performs storage, transmission, and processing of information based on spin properties of electrons.

The spin electronic device uses mainly a skyrmion. The skyrmion refers to a spin structure which has a specific directionality formed on the surface of a ferromagnetic layer, for example, a direction in which it converges to the center and a counterclockwise direction in which it rotates. Such a skyrmion has topological properties and shows a new physical phenomenon such as a topological hall effect and a skyrmion hall effect accordingly.

Much research is being devoted to the skyrmion. Particularly, after the fact that the skyrmion can exist at room temperature has been found, a lot of research is being conducted for the purpose of device application based on possibilities of electronic device application.

Because the skyrmion has a very small diameter of a several nanometers and has a relatively small minimum current density for starting operation, the skyrmion can be useful in constructing magnetic memories or logic elements. However, it can be said that the biggest problem in constructing a magnetic memory or a logic element by using the skyrmion is to generate or erase the skyrmion quickly in a controlled state.

Methods for generating the skyrmion by using an existing magnetic field, a current-induced spin torque, voltage-controlled magnetic anisotropy, or thermal energy have been researched and proposed.

The method using a magnetic field has many disadvantages in electronic element applications due to the magnetic field.

The method using a current-induced spin torque is able to generate, erase, or move the skyrmion by flowing a current on a plane. However, it is difficult to generate, erase, or move the skyrmion in a single element. Further, since the skyrmion itself is generated by defects of a thin film, the generated skyrmion is hard to move and the generation and erasure of the skyrmion are also greatly affected by the distribution of the defects, so that it may be difficult to use the skyrmion from the viewpoint of applications.

The method using the voltage-controlled magnetic anisotropy is to generate or erase the skyrmion by applying a voltage vertically. Since the method uses a three-dimensional structure, the method is advantageous in the application of devices which are combined with a two-dimensional structure and have various functionality. However, the method still has a disadvantage that the skyrmion is generated depending on the defect of a thin film so that it cannot freely and rapidly move.

In this regard, Korean Patent No. 10-1964904 discloses that when a sine wave current or cosine wave current is applied to a conducting wire, a rotational current is applied to the magnetic layer, thereby generating skyrmion. A paper “Creation of magnetic skyrmion bubble lattices by ultrafast laser in ultrathin films” discloses that bubble skyrmion is generated by applying vertically a single laser pulse for 35 femtoseconds.

### SUMMARY

Various embodiments relate to an apparatus for generating, erasing, or moving a skyrmion in a magnetic thin film.

Various embodiments of the present disclosure provide an apparatus for solving the aforementioned problems and for freely generating, erasing, and moving the skyrmion, and a method for the same.

The technical problem to be overcome in this document is not limited to the above-mentioned technical problems. Other technical problems not mentioned can be clearly understood from those described below by a person having ordinary skill in the art.

One embodiment is an apparatus for generating, erasing, and moving a skyrmion may include: a first electrode to which a first voltage for generating and erasing the skyrmion is applied; a second electrode to which a second voltage for moving the generated skyrmion is applied; a free layer having one end connected to a ground and the other end connected to the second electrode; a pinned layer which is connected to the first electrode; and a barrier layer which is provided between the free layer and the pinned layer and includes a conducting path connecting the free layer and the pinned layer.

The conducting path may be formed by applying a voltage capable of destroying insulation to a portion of the barrier layer.

The free layer may be formed by stacking tantalum oxide (TaOx), magnesium oxide (MgO), tantalum (Ta), CoFeB, and tungsten (W).

The apparatus may further include a controller which determines the first voltage applied to the first electrode and the second voltage applied to the second electrode.

The controller may control the skyrmion to be generated by applying a positive (+) voltage to the first electrode, and may control the skyrmion to be erased by applying a negative (−) voltage to the first electrode.

The controller may determine a magnitude of the positive (+) voltage applied to the first electrode based on the number of skyrmions to be generated, and may determine a magnitude of the negative (−) voltage applied to the first electrode based on the number of skyrmions to be erased.

The controller may control the skyrmion to move to one end of the free layer connected to the ground by applying the positive (+) voltage to the second electrode, and may control the skyrmion to move to the other end of the free layer to which the second electrode is connected, by applying the negative (−) voltage to the second electrode.

Another embodiment is a skyrmion racetrack memory including: a first electrode to which a first voltage for generating and erasing the skyrmion is applied; a second electrode to which a second voltage for moving the generated skyrmion is applied; a free layer having one end connected to a ground and the other end connected to the second electrode; a pinned layer which is connected to the first electrode; and a barrier layer which is provided between the free layer and the pinned layer and includes a conducting path connecting the free layer and the pinned layer. The free layer may be divided into a plurality of areas, and each of the plurality of areas may correspond to one bit. The area including the one end connected to the ground may represent the most significant bit, and the area including a location where the conducting path is connected may represent the least significant bit.

The conducting path may be formed by applying a voltage capable of destroying insulation to a portion of the barrier layer.

The free layer may be formed by stacking tantalum oxide (TaOx), magnesium oxide (MgO), tantalum (Ta), CoFeB, and tungsten (W).

The skyrmion racetrack memory may further include a controller which determines the first voltage applied to the first electrode and the second voltage applied to the second electrode.

The controller may control the skyrmion to be generated by applying a positive (+) voltage to the first electrode, and may control the skyrmion to be erased by applying a negative (−) voltage to the first electrode.

The controller may determine a magnitude of the positive (+) voltage applied to the first electrode such that one skyrmion is generated in the area which represents the least significant bit, and may determine a magnitude of the negative (−) voltage applied to the first electrode such that only one skyrmion in the area which represents the least significant bit is erased.

The controller may control the skyrmion to move to the area which represents a higher-order bit by applying the positive (+) voltage to the second electrode, and may control the skyrmion to move to the area which represents a lower-order bit by applying the negative (−) voltage to the second electrode.

The controller may determine a magnitude of the positive (+) voltage applied to the second electrode, enough such that the skyrmion is able to move to an area of a one-step higher-order bit.

The apparatus and method proposed in the present disclosure can freely generate and erase the skyrmion by using a vertical electrode.

The apparatus and method proposed in the present disclosure have many advantageous properties of a three-dimensional structure so that they can be easily applied to various fields of application.

Advantageous effects that can be obtained from the present disclosure are not limited to the above-mentioned effects. Further, other unmentioned effects can be clearly understood from the following descriptions by those skilled in the art to which the present disclosure belongs.

### BRIEF DESCRIPTION OF THE DRAWINGS

FIG. 1 shows a magnetic tunnel junction (MTJ) structure for generating a skyrmion;

FIG. 2 shows an MTJ structure-based apparatus for generating and erasing the skyrmion, proposed in the present disclosure;

FIG. 3 shows an example of generating the skyrmion by the apparatus for generating and erasing the skyrmion, proposed in the present disclosure;

FIG. 4 shows the number of the skyrmions generated according to a voltage applied to a first electrode 23 in the apparatus for generating and erasing the skyrmion, proposed in the present disclosure;

FIG. 5 shows an embodiment where the skyrmion is generated and erased in the apparatus for generating and erasing the skyrmion, proposed in the present disclosure;

FIG. 6 shows an embodiment where the skyrmion is generated, moved and erased in the apparatus for generating and erasing the skyrmion, proposed in the present disclosure; and

FIG. 7 shows an embodiment where the apparatus for generating and erasing the skyrmion, proposed in the present disclosure, is applied to a skyrmion racetrack memory.

With regard to the description of the drawings, the same or similar reference numerals may be used for the same or similar components.

### DETAILED DESCRIPTION

Hereinafter, embodiments of the present disclosure will be described in detail with reference to the accompanying drawings, in which the same or similar components will be given the same reference numerals, and redundant description thereof will be omitted.

In the following, specific details may be set forth to provide an understanding of the invention. However, it will be apparent to a person skilled in the art that the present invention may be practiced without these details. In addition, those of ordinary skill in the art will recognize that various embodiments of the present invention described below may be implemented in a variety of ways, such as a process, an apparatus, a system, or a method on a computer-readable medium.

The components shown in the drawings are only illustrating exemplary embodiments of the present invention, and are intended to avoid obscuring the invention. In addition, connections between components in the drawings are not limited to direct connections. Rather, data between these components may be modified, reformatted or otherwise changed by an intermediate component or device. Also, additional or fewer connections can be used. The terms “connected” or “communicatively connected” should be understood to include direct connections, indirect connections through one or more intermediary devices, and wireless connections.

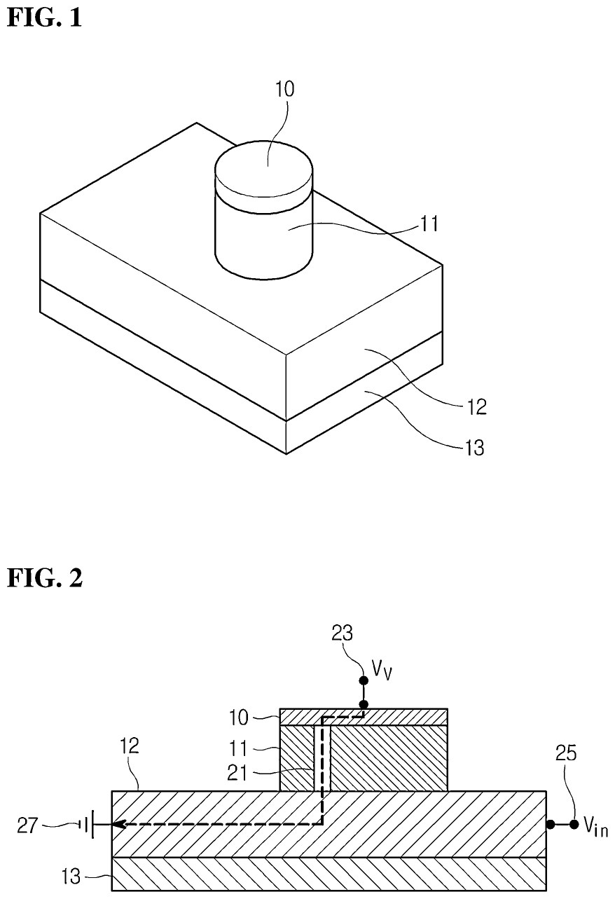

FIG. 1 shows a magnetic tunnel junction (MTJ) structure for generating a skyrmion.

Referring to FIG. 1, the MTJ structure for generating a skyrmion may include a pinned layer 10, a barrier layer 11, and a free layer 12. The skyrmion is a spin structure having a specific directionality. The center and the periphery of the skyrmion have spins in opposite directions to each other, and the direction of the spin is slightly changed as it goes from the periphery to the center. Such a skyrmion can be generated by applying a spin polarized current or voltage of a certain magnitude or more to the MTJ.

The generated skyrmion may move along with the current flowing through the free layer 12.

FIG. 2 shows an MTJ structure-based apparatus for generating and erasing the skyrmion, proposed in the present disclosure.

Referring to FIG. 2, in the apparatus for generating and erasing the skyrmion proposed in the present disclosure, the free layer 12, the barrier layer 11, and the pinned layer 10 are provided on a substrate 13, and in particular, the barrier layer 11 may include a conducting path 21 which connects the pinned layer 10 and the free layer 12. A first electrode 23 for applying a voltage Vv for generating and erasing the skyrmion may be connected to the pinned layer 10, and a second electrode 25 for applying a voltage Vin for controlling the movement of the generated skyrmion may be connected to one side of the free layer 12. The second electrode 25 for applying the voltage Vin may be connected. A ground 27 may be connected to the other side of the free layer 12.

The free layer 12 may be a ferromagnetic body formed by stacking tantalum oxide (TaOx), magnesium oxide (MgO), tantalum (Ta), CoFeB, and tungsten (W) on the substrate 13, and may be an area where the skyrmion is generated and moved.

The pinned layer 10 may be made of platinum (Pt), and the barrier layer 11 may be an insulation layer made of gadolinium oxide (GdOx).

Although not shown in FIG. 2, there may be provided a controller that determines a voltage to be applied to the first electrode 23 and the second electrode 25 and controls the determined voltage to be applied.

The conducting path 21 may be formed by destroying a portion of the barrier layer 11 through a method of applying a voltage enough to destroy an insulator to the barrier layer 11. However, the method of forming the conducting path 21 is not limited thereto, and the conducting path 21 can be formed by using any method that allows the free layer 12 and the pinned layer 10 to conduct.

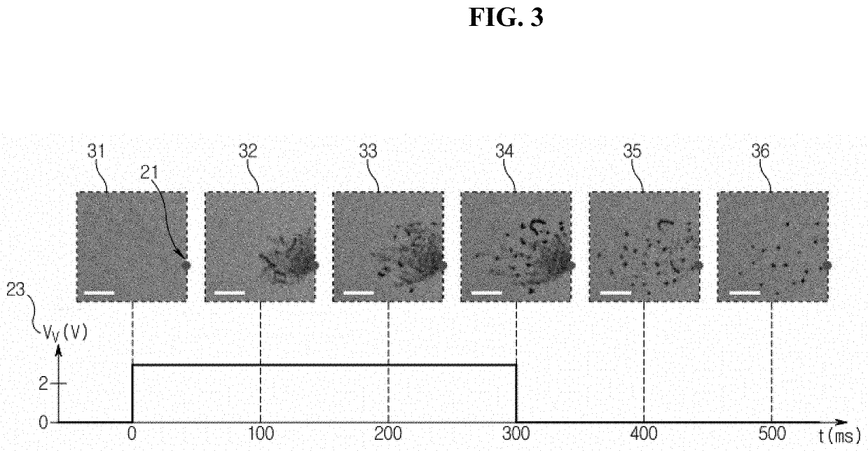

FIG. 3 shows an example of generating the skyrmion by the apparatus for generating and erasing the skyrmion, proposed in the present disclosure.

Referring to FIG. 3, the voltage Vv of about 2.5 V may be applied to the first electrode 23 for a period of 0 ms to 300 ms in order to generate the skyrmion.

The conducting path 21 in FIG. 3 may be located at positions indicated by a dot as shown in images 31 to 35.

The images of FIG. 3 are obtained by photographing with a magneto-optical Kerr Effect (MOKE) microscope. The images include the image 31 at 0 ms at which the voltage Vv is started to be applied to the first electrode 23, the image 32 at 100 ms, the image 33 at 200 ms, the image 34 at 300 ms at which the application of the voltage Vv to the first electrode 23 is terminated, the image 35 at 400 ms, and the image 36 at 500 ms, which are all for generating the skyrmion, respectively.

In each of the images, gray areas indicate that a magnetization direction corresponds to a direction coming out of the screen or paper, and black areas indicate that the magnetization direction corresponds to a direction coming into the screen or paper.

When the voltage Vv is applied through the first electrode 23, it can be seen that black dots are formed and spread out at the location of the conducting path 21 as shown in the image 32. Then, when the voltage Vv is no longer applied through the first electrode 23, the area in which the magnetization direction is not completely changed returns to the original magnetization direction, and only the area in which the magnetization direction is completely changed remains in the form of a dot as shown in the image 36, and as a result, the generation of the skyrmion is completed.

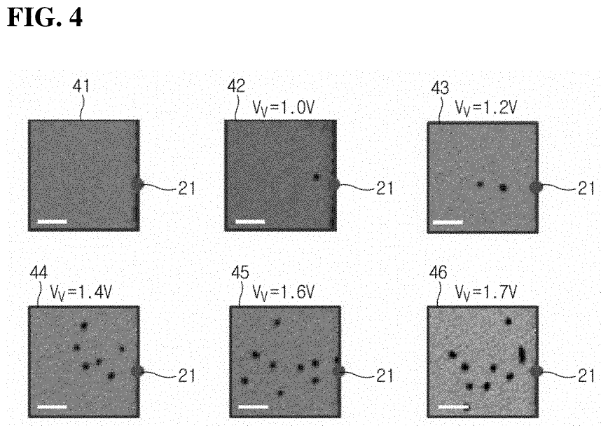

FIG. 4 shows the number of the skyrmions generated according to the voltage applied to the first electrode 23 in the apparatus for generating and erasing the skyrmion, proposed in the present disclosure.

Referring to FIG. 4, images 41 to 46 show that the skyrmions which are generated when the voltage applied to the first electrode 23 is 0 V, 1.0 V, 1.2 V, 1.4 V, 1.6 V, and 1.7 V, respectively.

Referring to FIG. 4, it can be seen that as the voltage applied to the first electrode 23 increases, the number of generated skyrmions increases. Accordingly, the number of generated skyrmions can be controlled by adjusting the strength of the voltage applied to the first electrode 23.

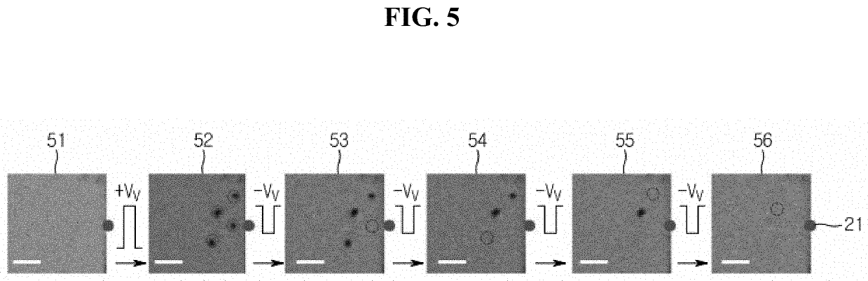

FIG. 5 shows an embodiment where the skyrmion is generated and erased in the apparatus for generating and erasing the skyrmion, proposed in the present disclosure.

Referring to FIG. 5, when a positive (+) voltage is applied in an initial state 51 where no voltage is applied to the first electrode 23, the skyrmion may be generated around the conducting path 21 as shown in FIG. 3 (see reference numeral 52). According to the embodiment, the voltage applied to the first electrode 23 may be sufficient to generate four skyrmions. Then, when a negative (−) voltage is applied to the first electrode 23, the generated skyrmions may be erased (see reference numerals 53 to 56). According to the embodiment, one skyrmion can be erased at a time by applying a low negative (−) voltage, or several skyrmions can be erased at a time by applying a high (−) voltage.

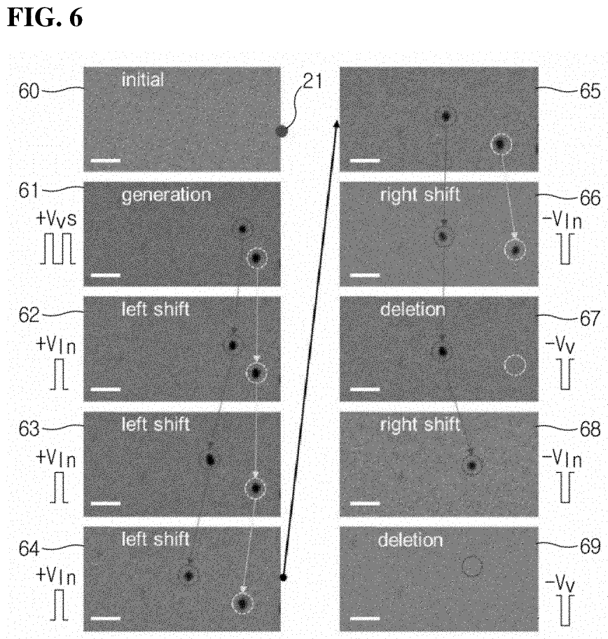

FIG. 6 shows an embodiment where the skyrmion is generated, moved and erased in the apparatus for generating and erasing the skyrmion, proposed in the present disclosure.

Referring to FIG. 6, when a positive (+) voltage is applied to the first electrode 23 in an initial state 60, the skyrmion may be generated (see reference numeral 61). Here, only a voltage sufficient to generate one skyrmion can be applied to the first electrode 23, and this may be repeated twice to generate two skyrmions.

When a positive (+) voltage is applied to the second electrode 25 in the state where the skyrmion has been generated, a horizontal current flows to the left due to the voltage difference in the free layer 12, and the skyrmion moves to the left by this current (see reference numerals 62, 63, 64, and 65).

Also, when a negative (−) voltage is applied to the second electrode 25, the horizontal current flows to the right due to the voltage difference in the free layer 12, the skyrmions moves to the right by this current (see reference numerals 66 and 68).

Also, when a negative (−) voltage is applied to the first electrode 23, the generated skyrmions may be erased (see reference numerals 67 and 69). According to the embodiment, the erasure of the skyrmion may start from the skyrmion closest to the conducting path 21.

Referring to FIG. 6, it can be found that the apparatus for generating and erasing the skyrmion proposed in the present disclosure is able to easily generate, erase, and move the skyrmion based on the voltage applied to the first electrode 23 and/or the second electrode 25.

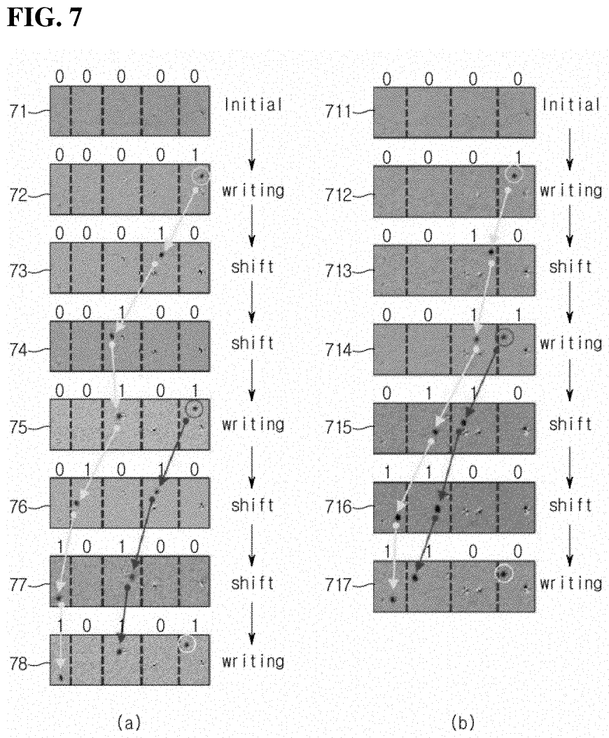

FIG. 7 shows an embodiment where the apparatus for generating and erasing the skyrmion, proposed in the present disclosure, is applied to a skyrmion racetrack memory.

Referring to FIG. 7, a skyrmion racetrack memory can be made by using the apparatus for generating and erasing the skyrmion proposed in the present disclosure. The racetrack memory may include an area for a plurality of bits having an area indicating the most significant bit on one side thereof and an area indicating the least significant bit on the other side thereof. According to the embodiment, the free layer 12 of FIG. 2 may be divided into areas capable of representing a plurality of bits. Here, an area adjacent to the ground 27 may represent the most significant bit, and an area adjacent to the conducting path 21 may represent the least significant bit. If there is a skyrmion in the area of the corresponding bit, the bit may be recognized as “1”, and if there is no skyrmion, the bit may be recognized as “0”.

The write operation of “10101” to the skyrmion racetrack memory is shown in (a) of FIG. 7. In FIG. 7, “writing” indicates that a positive (+) voltage is applied to the first electrode 23 in order to generate the skyrmion, and “shift” indicates that a positive (+) voltage is applied to the second electrode in order to move the generated skyrmion.

Referring to (a) of FIG. 7, the racetrack memory is composed of 5 bits. “Writing” is performed in an initial state 71 where all the bits of the racetrack memory have a value of “0” in order to write “10101” in the 5-bit area, so that a skyrmion can be generated in the area of the least significant bit (see reference numeral 72). Thus, the racetrack memory may have a value of “00001”. Then, the skyrmion is moved by one bit to the left by performing “shift” (see reference numeral 73), and then the racetrack memory has a value of “00010”. When the “shift” is performed one more time to move the skyrmion further one bit to the left (see reference numeral 74), the racetrack memory has a value of “00100”. Then, the “writing” is performed to generate the skyrmion in the area of the least significant bit (see reference numeral 75), the racetrack memory has a value of “00101”. Subsequently, when the skyrmion is moved by one bit to the left by performing the “shift” (see reference numeral 76), the racetrack memory has a value of “01010”. When the “shift” is performed one more time to move the skyrmion further one bit to the left (see reference numeral 77), the racetrack memory has a value of “10100”. Also, when the “writing” is performed to generate the skyrmion in the area of the least significant bit (see reference numeral 78), the racetrack memory finally has a value of “10101”.

Referring to (b) of FIG. 7, which is another embodiment, the racetrack memory is composed of 4 bits. The “Writing” is performed in an initial state 711 where all the bits of the racetrack memory have a value of “0” in order to write “1101” in the 4-bit area, so that a skyrmion can be generated in the area of the least significant bit (see reference numeral 712). Thus, the racetrack memory may have a value of “0001”. Then, the skyrmion is moved by one bit to the left by performing “shift” (see reference numeral 713), and then the racetrack memory has a value of “0010”. Then, the “writing” is performed to generate the skyrmion in the area of the least significant bit (see reference numeral 714), the racetrack memory has a value of “0011”. Subsequently, when the skyrmion is moved by one bit to the left by performing the “shift” (see reference numeral 715), the racetrack memory has a value of “0110”. When the “shift” is performed one more time to move the skyrmion further one bit to the left (see reference numeral 716), the racetrack memory has a value of “1100”. Also, when the “writing” is performed to generate the skyrmion in the area of the least significant bit (see reference numeral 717), the racetrack memory finally has a value of “1101”.

Unlike conventional methods, the apparatus for generating and erasing the skyrmion, proposed in the present disclosure, is not manufactured based on defects. Therefore, the apparatus can freely move the skyrmion, and can easily generate and move the skyrmion because the current density required to move the skyrmion is also much lower than that of the conventional method. Also, the apparatus includes the racetrack memory, thereby being sufficiently used for various purposes.

What is claimed is:

1. An apparatus for generating, erasing, and moving a skyrmion, the apparatus comprising:
a first electrode to which a first voltage for generating and erasing the skyrmion is applied;
a second electrode to which a second voltage for moving the generated skyrmion is applied;
a free layer having one end connected to a ground and the other end connected to the second electrode;
a pinned layer which is connected to the first electrode; and
a barrier layer which is provided between the free layer and the pinned layer and comprises a conducting path connecting the free layer and the pinned layer.

2. The apparatus of claim 1, wherein the conducting path is formed by applying a voltage capable of destroying insulation to a portion of the barrier layer.

3. The apparatus of claim 1, wherein the free layer is formed by stacking tantalum oxide (TaOx), magnesium oxide (MgO), tantalum (Ta), CoFeB, and tungsten (W).

4. The apparatus of claim 1, further comprising a controller which determines the first voltage applied to the first electrode and the second voltage applied to the second electrode.

5. The apparatus of claim 4, wherein the controller controls the skyrmion to be generated by applying a positive (+) voltage to the first electrode, and controls the skyrmion to be erased by applying a negative (−) voltage to the first electrode.

6. The apparatus of claim 5, wherein the controller determines a magnitude of the positive (+) voltage applied to the first electrode based on the number of skyrmions to be generated, and determines a magnitude of the negative (−) voltage applied to the first electrode based on the number of skyrmions to be erased.

7. The apparatus of claim 5, wherein the controller controls the skyrmion to move to one end of the free layer connected to the ground by applying the positive (+) voltage to the second electrode, and controls the skyrmion to move to the other end of the free layer to which the second electrode is connected, by applying the negative (−) voltage to the second electrode.

8. A skyrmion racetrack memory comprising:
a first electrode to which a first voltage for generating and erasing the skyrmion is applied;
a second electrode to which a second voltage for moving the generated skyrmion is applied;
a free layer having one end connected to a ground and the other end connected to the second electrode;
a pinned layer which is connected to the first electrode; and
a barrier layer which is provided between the free layer and the pinned layer and comprises a conducting path connecting the free layer and the pinned layer,
wherein the free layer is divided into a plurality of areas, and each of the plurality of areas corresponds to one bit,
and wherein the area comprising the one end connected to the ground represents the most significant bit, and the area comprising a location where the conducting path is connected represents the least significant bit.

9. The skyrmion racetrack memory of claim 8, wherein the conducting path is formed by applying a voltage capable of destroying insulation to a portion of the barrier layer.

10. The skyrmion racetrack memory of claim 8, wherein the free layer is formed by stacking tantalum oxide (TaOx), magnesium oxide (MgO), tantalum (Ta), CoFeB, and tungsten (W).

11. The skyrmion racetrack memory of claim 8, further comprising a controller which determines the first voltage applied to the first electrode and the second voltage applied to the second electrode.

12. The skyrmion racetrack memory of claim 11, wherein the controller controls the skyrmion to be generated by applying a positive (+) voltage to the first electrode, and controls the skyrmion to be erased by applying a negative (−) voltage to the first electrode.

13. The skyrmion racetrack memory of claim 12, wherein the controller determines a magnitude of the positive (+) voltage applied to the first electrode such that one skyrmion is generated in the area which represents the least significant bit, and determines a magnitude of the negative (−) voltage applied to the first electrode such that only one skyrmion in the area which represents the least significant bit is erased.

14. The skyrmion racetrack memory of claim 12, wherein the controller controls the skyrmion to move to the area which represents a higher-order bit by applying the positive (+) voltage to the second electrode, and controls the skyrmion to move to the area which represents a lower-order bit by applying the negative (−) voltage to the second electrode.

15. The skyrmion racetrack memory of claim 14, wherein the controller determines a magnitude of the positive (+) voltage applied to the second electrode, enough such that the skyrmion is able to move to an area of a one-step higher-order bit.
